(19) United States
(12) Patent Application Publication
(10) Pub. No.: US 2005/0068730 A1
(43) Pub. Date: Mar. 31, 2005

(54) Heat dissipation method for microprocessors

(76) Inventors: Yao-Nan Lin, Chilung (TW); Shang-Chih Yang, Changhua (TW); Tzu-Yi Kuo, Taipei (TW); Ting-Wen Chen, Taipei (TW)

Correspondence Address: BIRCH STEWART KOLASCH & BIRCH, PO BOX 747, FALLS CHURCH, VA, 22040-0747, US

(21) Appl. No.: 10/671,734

(22) Filed: Sep. 29, 2003

(51) Int. Cl. H05K 7/20

(52) U.S. Cl. 361/695

(57) ABSTRACT

A heat dissipation method for microprocessors to dissipate heat for a microprocessor of low power consumption includes a fan directly mounting on the microprocessor. The fan directs external cold air to the microprocessor to perform heat exchange and to achieve heat dissipation object.

### FIELD OF THE INVENTION

The present invention relates to a heat dissipation method for microprocessors adopted for use on low power consumption microprocessors.

### BACKGROUND OF THE INVENTION

In the issue of operation efficiency of microprocessors (such as Central Processing Unit-CPU, Graphics Processing Unit-GPU, and the like), it is well known that heat dissipation capability is one of the most important factors that decides whether the microprocessor can achieve the optimum performance. The operation temperature of microelectronic elements determines the reliability of electronic products.

The design of heat dissipation for conventional CPUs in the computer systems generally includes bonding a heat-sink to the CPU and mounting a fan on the heat-sink. Thermal energy generated by the CPU during operation is transferred to the heat-sink, and the fan channels cold air to the heat-sink to perform heat exchange, and heated air is discharged. When the operation frequency of the CPU increases, the demand for heat dissipation also increases. For instance, at present the copper heat-sink has replaced the aluminum heat-sink. And the rotation speed of the fan also is increased to the highest limit within allowable noise range.

In computer systems, as other microprocessors (such as GPU on the video graphics adapter card-VGA card) have increasing operation frequency. In order to maintain normal operation conditions the GPU also has heat dissipation requirement. The simplest approach to meet this requirement is adopting the method used on CPU, namely directly mounting a heat-sink and a fan on the GPU. However, one has to to take into account the space and weight limitations.

The operation frequency of GPUs on the VGA cards has increased significantly due to multimedia processing requirements. However not every user needs a high level VGA card. For instance users who use the computer system to process document operations do not need the high level VGA card. Hence ordinary VGA cards still are widely available in the market place. In the situation where a GPU is adopted heat dissipation approach like in the CPU, and heat dissipation requirement is permitted, the GPU on the VGA card usually has a heat-sink mounted thereon without a fan. This approach can discharge heat through the heat-sink and save the cost of a fan.

Moreover, for professional computer users, “over clocking” is an approach to achieve improved computer performance at a lower cost. Hence over clocking the CPU in the computer systems has become increasingly popular. Similarly, over clocking GPU on the VGA card also is one of the targets for professional computer users. However, with only a heat-sink mounting onto the GPU on the VGA card, when the GPU is over clocking, the operation temperature increases. The original heat-sink cannot provide higher heat dissipation efficiency as required. The GPU is easily burned out.

### SUMMARY OF THE INVENTION

In view of the aforesaid disadvantages of the conventional heat dissipation methods that adopt the heat-sink with fan originally used for CPU: there is a greater power consumption. This results in higher costs, or directly bonds the heat-sink to the microprocessor that results in performance deficiency. Further, they don't meet the requirements of professional users in the ‘over clocking’ environment that could even cause burn-out of the microprocessor. As a result, the primary object of the invention is to provide a heat dissipation method for microprocessors adopted for use mainly on low power consumption microprocessors. The method includes steps of:

selecting a microprocessor which consumes power between 7 Watts and 25 Watts;

mounting a fan on the microprocessor;

rotating the fan to direct cold air in the inlet of the fan to the microprocessor; and

proceeding heat transfer between the cold air and the microprocessor, and discharging heated air.

The heat dissipation method for microprocessors of the invention can achieve optimal price ratio performance when used in low power consumption microprocessors. It also meets the heat dissipation requirement when the microprocessor is over clocking.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of the invention.

### DESCRIPTION OF THE PREFERRED EMBODIMENT

The heat dissipation method for microprocessors according to the invention aims at low power consumption microprocessors such as south bridge chips, north bridge chips or video graphics processors on the VGA cards.

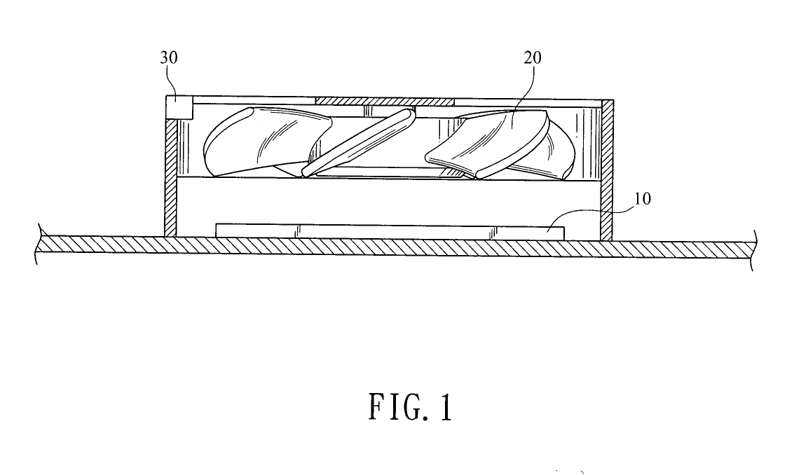

Refer to FIG. 1 for the heat dissipation assembly of the invention. It includes a microprocessor 10 and a fan 20. The heat dissipation method of the invention is to directly mount the fan 20 on the microprocessor 10.

Based on the heat dissipation method of the invention, an experiment has been performed. The experiment is done in an environment at a temperature of 37.5° C. and uses the same microprocessor under different power consumption settings, to measure the surface temperature and working conditions of the microprocessor. The experiment includes a first set which has a heat-sink directly bonding to the microprocessor (with field airflow speed of 1 M/sec in the testing environment), a second set which has the heat-sink bonding to the microprocessor and a fan mounting on the heat-sink, and a third set, which is the invention, that has the fan directly mounted on the microprocessor. Test results are shown in the Table 1 below:

TABLE 1
Heat dissipation tests for different types of heat-sink assembly

| | 7 Watts | 15 Watts | 20 Watts | 25 Watts | 30 Watts | 60 Watts | 90 Watts |
|---|---|---|---|---|---|---|---|
| 1^{st}. set | Tj = 78° C. | Tj = 125.5° C. | Tj = 154.5° C. | Tj = 183.5° C. | Tj = 212° C. | N.A. | N.A. |
| 2^{nd}. Set | Tj = 50.8° C. | Tj = 66° C. | Tj = 75.5° C. | Tj = 85° C. | Tj = 92° C. | Tj = 140° C. | Tj = 205° C. |
| 3^{rd}. set | Tj = 61.5° C. | Tj = 89.2° C. | Tj = 106.5° C. | Tj = 122° C. | Tj = 138° C. | Tj = 241° C. | N.A. |

The maximum temperature for general microprocessors should not exceed 125° C. According to Table 1, the first set which has only one heat-sink bonding to the microprocessor: when the power consumption of the microprocessor is 15 Watts, the temperature of the microprocessor exceeds 125° C. Hence the microprocessor cannot withstand such high temperature and will be burned out.

The third set is the invention that has the fan directly mounted onto the microprocessor. When the power consumption of the microprocessor is 30 Watts, the temperature of the microprocessor has exceeded 125° C., and the microprocessor cannot withstand such high temperature and will be burned out. However, in the range of 7 Watts and 25 Watts, the heat dissipation power of the invention is sufficient.

Experiment 2 is an “over clocking” test on the microprocessor and memory of a VGA card by using a software 3DMark2001 developed by MadOnion & Co. The power consumption of the microprocessor on the VGA card is set in the range of 8 Watts and 18 Watts. The standard operation time clock of the microprocessor is 250 MHz. The standard operation time clock of the memory is 400 MHz. Three sets of test have been performed. The test results are shown in Table 2 below:

TABLE 2
Over clocking tests for different types of heat-sink assembly

| | GPU clock | MEM clock | Performance |
|---|---|---|---|
| Standard value | 250 MHz | 400 MHz | 7393 |
| First set | 260 MHz | 450 MHz | 7684 |
| Second set | 285 MHz | 540 MHz | 8375 |
| Third set | 285 MHz | 540 MHz | 8366 |

The test results in Table 2 show that in the situation of over clocking operation on the same VGA card, the performance of the third set of the invention exceeds the first set by far. Hence the experiments 1 and 2 depicted above prove that the heat-sink assembly of the invention can achieve the object desired.

The heat dissipation method according to the invention includes steps of:

A. selecting a microprocessor which has a power consumption between 7 Watts and 25 Watts;

B. mounting a fan on the microprocessor;

C. rotating the fan to direct cold air in the inlet of the fan to the microprocessor; and

D. proceeding heat transfer between the cold air and the microprocessor, and discharging heated air.

The heat dissipation method of the invention also includes consideration of issuing signals in the event of fan dysfunction to avoid the microprocessor from being burned out, due to failure of heat dissipation. Hence the fan has a sensor 30 located thereon. When the fan cannot rotate, the sensor 30 issues a signal which can trigger a buzzer or an indicating light to generate sound or blinking light for warning. The warning signal may also be displayed on a display screen through a computer software setting. Or the signal may be transformed to a command to stop the operation of the microprocessor through a computer software setting.

While the preferred embodiments of the invention have been set forth for disclosure, modifications of the disclosed embodiments of the invention as well as other embodiments thereof may occur to those skilled in the art. Accordingly, the appended claims are intended to cover all embodiments, which do not depart from the spirit and scope of the invention.

1. A heat dissipation method for microprocessors, comprising steps of:
mounting a fan on a microprocessor;
rotating the fan to direct cold air from the fan periphery to the microprocessor; and
proceeding heat transfer between the cold air and the microprocessor, and discharging the heated cold air.

2. The heat dissipation method of claim 1, wherein power consumption of the microprocessor ranges from 7 Watts to 25 Watts.

3. The heat dissipation method of claim 2, wherein the temperature of power consumption of the microprocessor ranges from 61° C. to 122° C.

4. The heat dissipation method of claim 1, wherein the fan generates a signal through a sensor when the fan stops rotation during the microprocessor performing processing.

5. The heat dissipation method of claim 4, wherein the signal is a warning signal.

6. The heat dissipation method of claim 4, wherein the signal is a command ordering the microprocessor to stop operation.

7. A heat dissipation method for microprocessors, comprising steps of:
deciding a microprocessor that consumes power between 7 Watts and 25 Watts and requires heat dissipation;
mounting a fan on the microprocessor;
rotating the fan to direct cold air from the fan periphery to the microprocessor; and
proceeding heat transfer between the cold air and the microprocessor, and discharging the heated cold air.

8. The heat dissipation method of claim 7, wherein the temperature of power consumption of the microprocessor ranges from 61° C. to 122° C.

9. The heat dissipation method of claim 7, wherein the fan generates a signal through a sensor when the fan stops rotation during the microprocessor performing processing.

10. The heat dissipation method of claim 9, wherein the signal is a warning signal.

11. The heat dissipation method of claim 9, wherein the signal is a command ordering the microprocessor to stop operation.

12. A heat dissipation assembly for microprocessors, comprising:
a microprocessor which has power consumption ranges from 7 Watts to 25 Watts; and
a fan mounting on the microprocessor to direct cold air from the fan periphery to the microprocessor.

13. The heat dissipation assembly of claim 12, wherein the fan includes a sensor to generate a signal when the fan stops rotation.

14. The heat dissipation assembly of claim 12, wherein the signal is a warning signal.

15. The heat dissipation assembly of claim 12, wherein the signal is a command ordering the microprocessor to stop operation.
